(19) United States
(12) Patent Application Publication
(10) Pub. No.: US 2017/0355826 A1
(43) Pub. Date: Dec. 14, 2017

(54) CARBOSILANE POLYMERS

(71) Applicant: Honeywell International Inc., Morris Plains, NJ (US)

(72) Inventors: Yamini Pandey, Fremont, CA (US); Joseph T. Kennedy, San Jose, CA (US); Helen X. Xu, Sunnyvale, CA (US)

(21) Appl. No.: 15/528,154

(22) PCT Filed: Nov. 22, 2015
(86) PCT No.: PCT/US2015/062045

§ 371 Date: May 19, 2017

Related U.S. Application Data
(60) Provisional application No. 62/085,892, filed on Dec. 1, 2014.

(51) Int. Cl. C08G 77/50; C09D 183/14; C09D 143/04; C08K 3/36; C08F 130/08; H01L 21/02

(52) U.S. Cl. CPC C08G 77/50; C08K 3/36; C08F 130/08; C09D 183/14; C09D 143/04; H01L 21/02118

(57) ABSTRACT

A composition comprising a carbosilane polymer formed from at least one carbosilane monomer and at least one carbonyl contributing monomer. In some embodiments, the composition is suitable as gap filling and planarizing material, and may optionally include at least one chromophore for photolithography applications.

### CROSS-REFERENCE TO RELATED APPLICATIONS

This application claims the benefit under Title 35, U.S.C. §119(e) of U.S. Provisional Application Serial No. 62/085,892 entitled CARBOSILANE POLYMERS, filed on Dec. 1, 2014, the entire disclosure of which is expressly incorporated by reference herein.

### FIELD OF THE INVENTION

The present disclosure relates generally to carbosilane polymers, and more particularly to carbosilane polymers formed from a carbosilane monomer component and a carbonyl contributing monomer.

### BACKGROUND

In advanced semiconductor manufacturing processes, there is a growing demand for highly planarizing materials which not only provide a void free fill of narrow spaced topographies, but are also able to furnish a planar surface. These materials may be bottom antireflective coatings (BARC), which have reflection control properties. Additionally, the material may be sacrificial, where it must be selectively removable by wet removal chemistries without damaging the underlying or other exposed films or substrates.

FIG. 1A illustrates an exemplary substrate 10 to be coated with a planarizing coating. FIG. 1A further shows a plurality of illustrative trenches 12 separated by features 14 on the surface of substrate 10.

An ideal case of an applied coating 16 following application and baking is presented in FIG. 1B. In the ideal case, the surface 18 of coating 16 has a perfectly even coating, whether the surface 18A is positioned above a trench 12, or the surface 18B is positioned above a feature 14. Such an ideal case is impossible to achieve.

A more typical case of an applied coating 16 following application and baking is presented in FIG. 1C. In the typical case, the surface 18 of coating 16 is not perfectly even, and at least partially follows the height of the trenches 12 and features 14. For example, the surface 18A positioned above a trench 12 is typically lower than the surface 18B positioned above a feature 14. A global planarity value can be calculated for the applied coating 16 by the formula:

Global planarity=(film thickness on top of widest feature as measured at the center of the feature+trench depth)−film thickness in center of widest trench

As the global planarity values approach zero, the surface 18 of coating 16 approaches a perfectly even coating, as illustrated in FIG. 1B. Generally, lower global planarity values are preferred.

Referring next to FIG. 2A, a more complicated substrate 20 including trenches 12 and features 14 is illustrated. Substrate 20 illustratively includes a first region including one or more relatively narrow trenches 12A, and a second region 24 including one or more relatively wide trenches 12B.

A typical applied coating 16 following application and baking is presented in FIG. 2B. As illustrated in FIG. 2B, the surface 18 of the coating 16 is not perfectly even, although the surface 18 above the first region 22 is more planar than the surface 18 above the second region 24.

The planarity of the surface 18 in FIG. 2B can be calculated by the formula:

Film thickness at center on top of the widest feature—film thickness at center at center on top of narrowest feature

The above formula corresponds to (A-B) in FIG. 2B. The planarity of the surface 18 in FIG. 2B can alternatively be calculated by the formula:

(Film thickness on top of space next to wide features +Height of wide features)−Film thickness in center of wide features

The above formula corresponds to (B+C)-D in FIG. 2B.

Improvements in the foregoing are desired.

### SUMMARY OF THE INVENTION

The present disclosure provides a composition comprising a carbosilane polymer formed from at least one carbosilane monomer component and at least one carbonyl contributing monomer.ln some embodiments, the compositionis suitable as gap filling and planarizing material, and may optionally include at least one chromophore for photolithography applications.

In one exemplary embodiment, a sacrificial spin on organocarbosiloxane film is formed by combining either one or more monomers in a suitable reaction media resulting in the formation of a homopolymer or a copolymer. The alkoxy monomer/monomers were combined in a solvent blend of safe and common industry solvents to which acid solution was added to catalyze the hydrolysis-condensation reaction. This reaction solution was heated at optimized time and temperature to form a low molecular weight and stable polymer.

In one exemplary embodiment, formulations which are 248 nm or 193 nm UV absorbing are formed by incorporating one or more chromophores that absorb 248 nm or 193 nm wavelength UV light. In some embodiments, the formulations have a molecular weight range from about 800 to about 2500 amu. In some embodiments, this molecular weight range provides desirable high wet etch and plasma etch rates.

According to an embodiment of the present disclosure, a composition comprises a carbosilane polymer, wherein the carbosilane polymer is formed from at least one carbosilane monomer and at least one carbonyl contributing monomer. In one embodiment, the carbosilane polymer has a silica content of from 10 wt. % to 45 wt. % or a carbonyl content of 3 wt. % or greater, based on the total weight of polymer. In one more particular embodiment, the carbosilane polymer has a silica content of from 10 wt. % to 45 wt. %. In one more particular embodiment, the carbosilane polymer has a carbonyl content of 3 wt. % or greater. In one more particular embodiment, the carbosilane polymer has a silica content of from 10 wt. % to 45 wt. % and a carbonyl content of 3 wt. % or greater

In a more particular embodiment of any of the above embodiments, the carbosilane polymer has a silica content from 13 wt. % to 30 wt. %, and a carbonyl content of 3 wt. % or greater.

In a more particular embodiment of any of the above embodiments, the carbosilane monomer is of the formula:

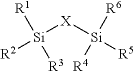

wherein: X is selected from linear or branched C₁-C₁₂ alkyl or C₆-C₁₄ aryl, and each R is either a hydrolysable group,a group that is reactive resulting in cross-linking through the group, or a terminal end group that does not participate in cross-linking. In a still more particular embodiment, the carbosilane monomer is Bis(Triethoxysilyl)Ethane.

In a more particular embodiment of any of the above embodiments, the carbonyl contributing monomer is selected from an acrylic monomer, a carboxylic containing monomer, and an anhydride monomer. In a more particular embodiment, the carbonyl contributing monomer is methacryloxypropyltrimethoxysilane.

In a more particular embodiment of any of the above embodiments, the composition further includes at least one crosslink promoter. In one even more particular embodiment, the crosslink promoter is an aminosilane salt of the formula:

Si(OR)₃(CH₂)ₙNH₃⁺(F₃CSO₃)⁻

wherein n is an integer from 1-10, each R is independently a C1-C₂₀ alkyl. In a more particular embodiment, the crosslink promoter is an aminopropyltriethyl silane. In a still more particular embodiment, the crosslink promoteris APTEOS triflate.

In a more particular embodiment of any of the above embodiments, the composition further includes at least one solvent. In one even more particular embodiment, the solvent comprises a planarizing enhancer, such as an alkyl carbonate. In a still more particular embodiment, the planarizing enhancercomprises propylene carbonate.

In a more particular embodiment of any of the above embodiments, the carbosilane polymer has a molecular weight of 1,000 or less. In another more particular embodiment of any of the above embodiments, the carbosilane polymer has a molecular weight ofabout 800 to about 1500, about 800 to about 2500, or about 800 to about 5000.

In a more particular embodiment of any of the above embodiments, the composition further includes at least one chromophore. In a more particular embodiment, the chromophore comprises at least one of PTEOS and TESAC. In another embodiment, the composition does not include a chromophore.

In a more particular embodiment of any of the above embodiments, the carbosilane polymer is further formed from at least one organoalkoxysilanemonomer. In one even more particular embodiment, the organoalkoxysilanemonomer is selected from methyltrimethoxysilane (MTMOS), methyltriethoxysilane (MTEOS), dimethyldiethoxysilane (DMDEOS), phenyl triethoxysilane (PTEOS), dimethyldimethoxysilane, phenyltrimethoxysilane, diphenyl diethoxysilane, diphenyl dimethoxysilane, and 9-anthracene carboxy-alkyl trialkoxysilanes.

According to another embodiment of the present disclosure, a film is formed by applying any of the above embodiments onto a surface and baking the composition to form the film.

According to another embodiment of the present disclosure, a method of forming a composition is provided. The method includes reacting at least one carbosilane monomer and at least one carbonyl contributing monomer to form a carbosilane polymer.ln a more particular embodiment, the carbosilane polymer has a silica content from 10 wt. % to 45 wt. %. In another more particular embodiment, the carbosilane polymer has a carbonyl content of 3 wt. % or greater. In still another more particular embodiment, the carbosilane polymer has a silica content from 13 wt. % to 30 wt. % and a carbonyl content of 3 wt. % or greater.

In a more particular embodiment, the methodincludes reacting the monomers at a temperature between about 50° C. and 90° C. for a time from about 1 hour to about 5 hours.

In a more particular embodiment of any of the above embodiments, the composition further includes at least one solvent. In one even more particular embodiment, the solvent comprises a planarizing enhancer, such as an alkyl carbonate. In a still more particular embodiment, the planarizing enhancer is propylene carbonate.

In one exemplary embodiment, a composition is provided. The composition includes at least one monomer selected from a carbosilane monomer, a carbonyl contributing monomer, and an organoalkoxysilane monomer; and at least one solvent, wherein the solvent comprises a planarizing enhancer, such as an alkyl carbonate. In a more particular embodiment, the planarizing enhancer comprises propylene carbonate. In one more particular embodiment, the solvent comprises a first solvent such as PGMEA or isoamyl alcohol and propylene carbonate. In one more particular embodiment of any of the above embodiments, the composition further comprises a chromophore. In one more particular embodiment of any of the above embodiments, the composition further comprises nitric acid. In one more particular embodiment of any of the above embodiments, the solvent comprises a first solvent and a planarizing enhancer such as propylene carbonate. In one more particular embodiment of any of the above embodiments, at least one monomer comprises at least one organoalkoxysilane monomer selected from the group consisting of methyltrimethoxysilane (MTMOS), methyltriethoxysilane (MTEOS), dimethyldiethoxysilane (DMDEOS), phenyl triethoxysilane (PTEOS), dimethyldimethoxysilane, phenyltrimethoxysilane, diphenyl diethoxysilane, diphenyl dimethoxysilane, and 9-anthracene carboxy-alkyl trialkoxysilanes. In one more particular embodiment of any of the above embodiments, at least one monomer comprises at least one carbosilane monomer selected from the group consisting of, BTSE, 1,2-Bis(Triethoxysilyl)Methane, 4,4-(Bis(triethoxysilyl)-1, 1-biphenyl, and 1-4-(Bis(triethoxysilyl)benzene. In one more particular embodiment of any of the above embodiments, at least one monomer comprises at least one carbonyl contributing monomer selected from the group consisting of an acrylic monomer, a carboxylic containing monomer, or an anhydride containing monomer. In an even more particular embodiment, the at least one monomer comprises methacryloxypropyltrimethoxysilane.

### BRIEF DESCRIPTION OF THE DRAWINGS

The above-mentioned and other features and advantages of this disclosure, and the manner of attaining them, will become more apparent and the invention itself will be better understood by reference to the following description of embodiments of the invention taken in conjunction with the accompanying drawings, wherein:

FIG. 1A illustrates an exemplary substrate prior to coating.

FIG. 1B illustrates an ideal coating applied to the exemplary substrate of FIG. 1A.

FIG. 1C illustrates another coating applied to the exemplary substrate of HG.

FIG. 2A illustrates another exemplary substrate including low and high density regions.

FIG. 2B illustrates a coating applied to the exemplary substrate of FIG. 2A.

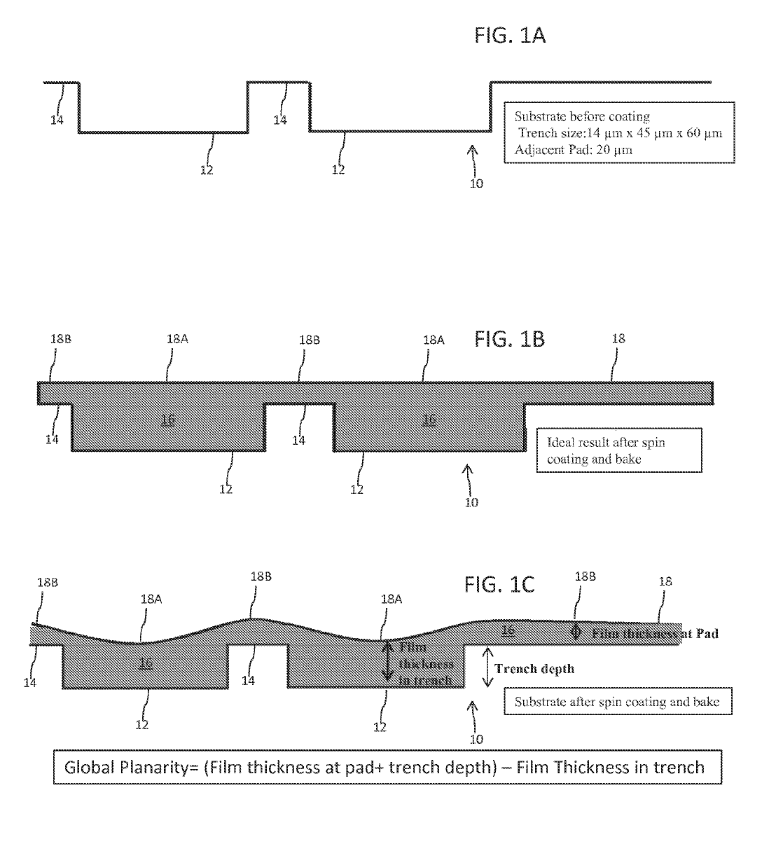

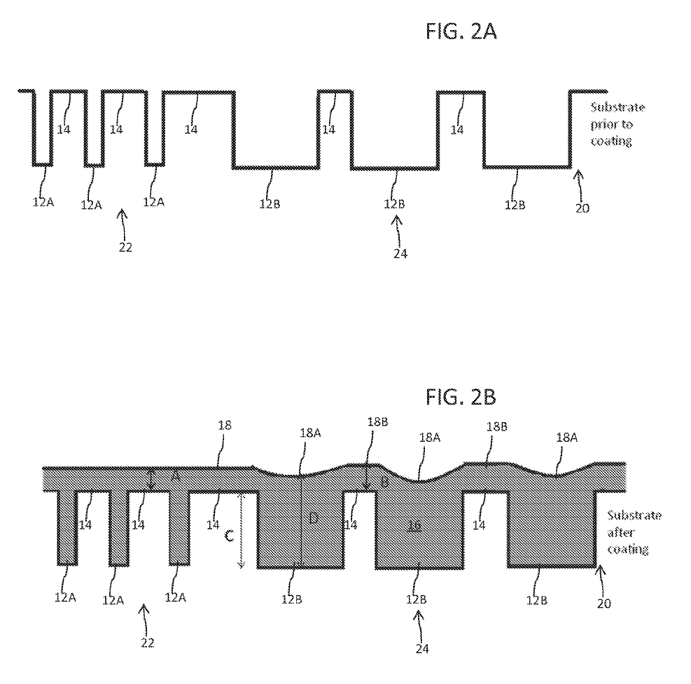

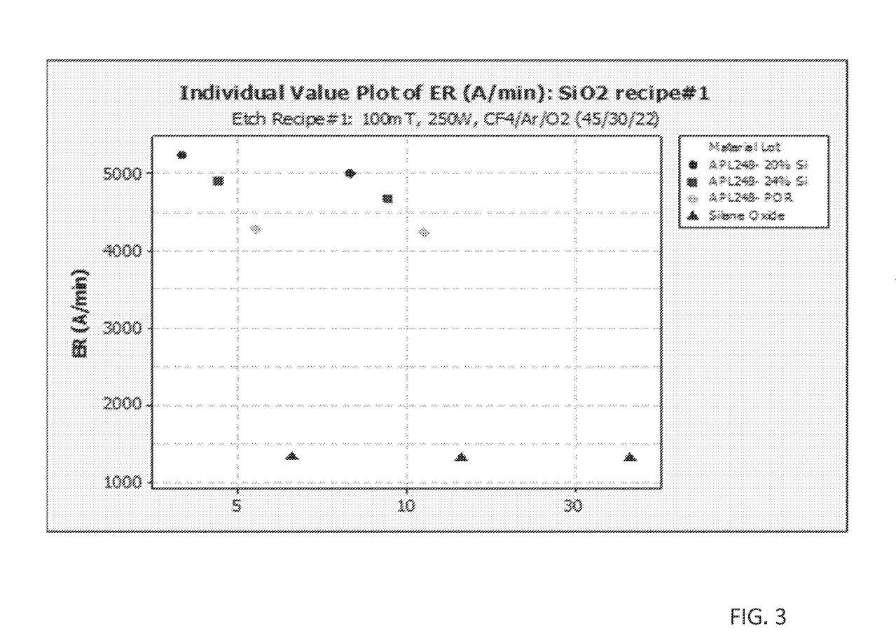

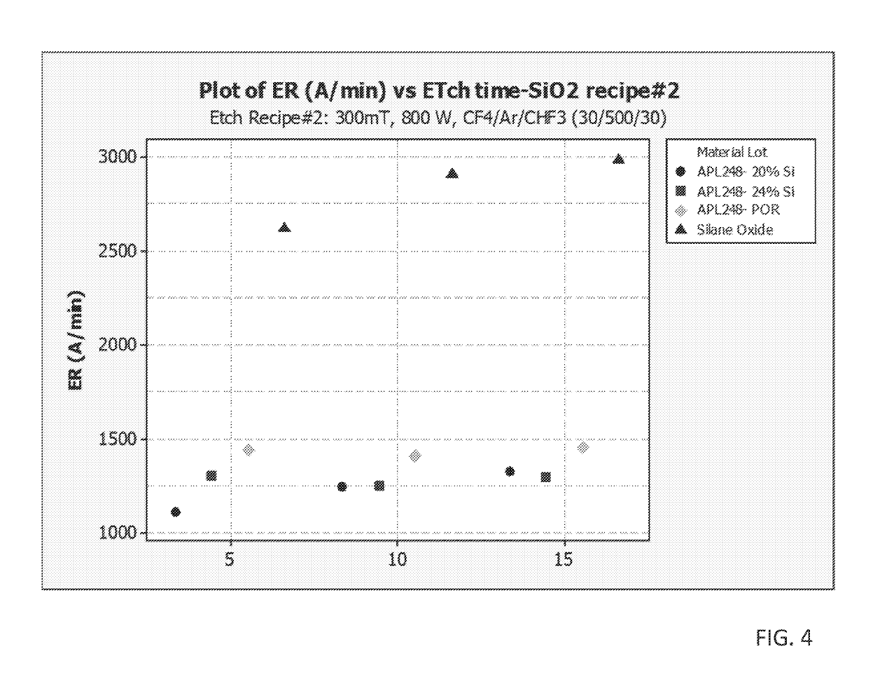

Corresponding reference characters indicate corresponding parts throughout the several views. The exemplifications set out herein illustrate exemplary embodiments of the invention and such exemplifications are not to be construed as limiting the scope of the invention in any manner.

### DETAILED DESCRIPTION

### A. Gap Fill and Planarizing Material

In one exemplary embodiment, a gap fill or planarizing material is formed from a composition, The composition includes a carbosilane polymer. The composition may optionally include one or more of a crosslink promoter, a solvent, a chromophore, or a catalyst.

In some exemplary embodiments, the material is formed as a gap filling or planarizing layer on a suitable substrate, Exemplary substrates include a dielectric film, a polysilicon film, a dielectric-metal layer, a metal-silicon layer, or an organic layer, such as positioned on a silicon wafer as used in semiconductor manufacturing processes.

In some exemplary embodiments, the formed layer has a planarity value of about 61, about 58, about 48, or less, or within any range defined by any two of the foregoing values.

In one exemplary embodiment, the formed layer has a thickness as great as about 500 nm, about 400 nm, about 300 nm, as little as about200 nm, about100 nm, about70 nm, or within any range defined by any two of the foregoing values.

In one exemplary embodiment, the formed layer is sacrificial in aqueous base stripper chemistries, such as ammonium hydroxide at elevated temperatures or J.T. Baker CLk-888 Stripper and Residue Remover, available from Avantor Performance Materials, but is resistant to room temperature 2.3 aqueous tetramethyl ammonium hydroxide (TMAH), n-butyl acetate (nBA), SC1at 40 C and 70 C (29%Ammonium hydroxide+31%Hydrogenperoxide+Dlwater in the volumetric ratio of 1/18/60) and propylene glycol methyl ether acetate (PGMEA).

### B. Carbosilane Polymer

In one exemplary embodiment, the gap-filling or planarizing material is formed from a composition including a carbosilane polymer. The carbosilane polymer includes a carbosilane monomer and a carbonyl contributing monomer.

In one embodiment, the carbosilane polymer comprises as little as about 0 wt. %, about 1 wt. % about 15 wt. %, about 30 wt. %, as great asabout80 wt. %,about90 wt. %,about 99 wt. %, about100 wt. %, of the total weight of the composition on a wet basis, or within any range defined by any two of the foregoing values, such as 1 wt. % to 99 wt. %, 15 wt. % to 90 wt. %, or 30 wt. % to 80 wt. %.

In one exemplary embodiment, the carbosilane polymer is a random copolymer of the carbosilane monomer and carbonyl contributing monomer unitscomprising oligomer units of varying size. In another exemplary embodiment, the carbosilane polymer is an alternating copolymer with regular alternating carbosilane monomer and carbonyl contributing monomer units. in still another exemplary embodiment, the carbosilane polymer is a block copolymer comprising silane monomer and carbonyl contributing monomer units.

In one exemplary embodiment, the carbosilane polymer has a silica content based on the total weight of polymeras little as about 10wt. %, about 13 wt. %,about 15 wt. %, about20 wt. %, as great as about 25 wt. %, about 30 wt. %, about 45 wt. %, or within any range defined by any two of the foregoing values, such as from about 10 wt. % to about 45 wt%, or about 13 wt. % to about 30 wt. %.

In one exemplary embodiment, the carbosilane polymer has a carbonyl content of about 3 wt. %, about 5 wt%, about 10 wt. %, about 13 wt. %, about 14 wt. %, about 15 wt%, about 20 wt%, or greater, or within any range defined by any two of the foregoing values, such as about 3 wt% to 20 wt. %, about 5 wt. % to about 15 wt. %, about 10 wt. % to about 15 wt. %, or about 13 wt. % to about 14 wt. %.

In one embodiment, the carbosilane polymer has a silica content as little as about 10 wt. %, about 13 wt. %, about 15wt. %, about 20wt. %, as great as about 25wt. %, about 30wt. %, about 45 wt. %, or within any range defined by any two of the foregoing values, and a carbonyl content of 3 wt. %, about 5 wt. %, about 10 wt. %, about 20 wt. %, or greater, or within any range defined by any two of the foregoing values, such as a silica content of about 10 wt% to about 45 wt. % and a carbonyl content of 3 wt. % to about 20 wt. %, or a silica content of about 15 wt% to about 25 wt% and a carbonyl content of about 5 wt. % to about 10 wt. %.

In one exemplary embodiment, the carbosilane polymer has a weight-average molecular weight in Daltons of as great as 5000, 3500, 2500, 2000, 1500, as little as 1000, 800, 500, or less, or within any range defined by any two of the foregoing values, such as 1,000 or less, 800 to 3500, 800 to 2500, or 800 to 1500.

### 1. Carbosilane Monomer

The carbosilane polymer is formed in part from a carbosilane monomer component. In one exemplary embodiment, the carbosilane monomer is of the formula:

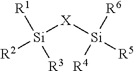

wherein: X is selected from linear or branched C₁-C₁₂ alkyl or C₆-C₁₄ aryl, and each R is a hydrolysable group or non-hydrolysable group, In one more particular embodiment, X is selected from a linear C₁-C₁₂ alkyl. In an even more particular embodiment, X is selected from methyl, ethyl, phenyl, diphenyl, ethylene, and naphyl. In a still more particular embodiment, X is ethyl.

Exemplary hydrolysable groups include C₁-C₁₂ alkoxy, C₁-C₁₂ alkylthio, haloalkoxy. Exemplary non-hydrolysable groups include C₁-C₁₂ alkyl, phenyl, aryl, vinyl, acrylate, epoxy, and acetyl.ln a more particular embodiment, each R is independently selected from a C₁-C₁₂ alkoxy, and even more particularly, each R is independently selected from methyoxy, ethoxy,isopropoxy, acetoxy, vinyl, epoxy, and acetyl. In one exemplary embodiment, each R is ethoxy or methoxy, and in a still more particular embodiment, each R is ethoxy.

In one exemplary embodiment, the carbosilane monomer comprises1,2-Bis(Triethoxysilyl)Ethane (“BTSE”). BTSE has the formula:

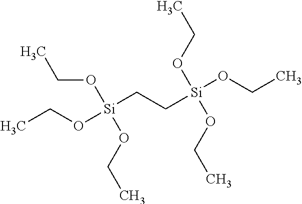 [SMILES: CCO[Si](CC[Si](OCC)(OCC)OCC)(OCC)OCC]

In one exemplary embodiment, the carbosilane monomer comprises 1 ,2-Bis(Triethoxysilyl)Methane. 1,2-Bis(Triethoxysilyl)Methane has the formula:

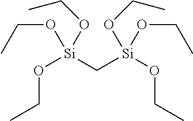 [SMILES: CCO[Si](C[Si](OCC)(OCC)OCC)(OCC)OCC]

In one exemplary embodiment, the carbosilane monomer comprises 4,4-(Bis(triethyoxysilyl)-1,1-biphenyl. 4,4-(Bis(triethyoxysilyl)-1,1 -biphenyl has the formula:

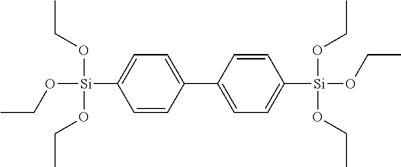 [SMILES: CCO[Si](OCC)(OCC)c1ccc(-c2ccc([Si](OCC)(OCC)OCC)cc2)cc1]

In one exemplary embodiment, the carbosilane monomer comprises 1,4-(Bis(triethoxysilyl)benzene. 1,4-(Bis(triethoxysilyl)benzene has the formula:

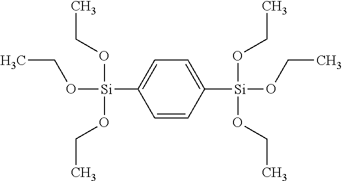 [SMILES: CCO[Si](OCC)(OCC)c1ccc([Si](OCC)(OCC)OCC)cc1]

### 2. Carbonyl Contributing Monomer

The carbosilane polymer is formed in part from a carbonyl contributing monomer. In one exemplary embodiment, the carbonyl contributing monomer includes a reactive moiety selected from an acrylic moiety, a carboxylic moiety, and an anhydride moiety. Without wishing to be bound by any theory, it is believed that the carbonyl group is easier to be reduced in a hydrogen or nitrogen environment, increasing the dry etch rate. It is further believed that the carbonyl containing moiety is more responsive to an amine type solution for digestions, improving the wet etch rate.

hi one exemplary embodiment, the carbonyl contributing monomer is an acrylic monomer of the formula:

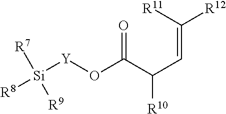

wherein: Y is selected from a linear or branched C₁-C₁₂ alkyl, each of R⁷, R⁸, and R⁹ is a hydrolysable group or non-hydrolysable group, and each of R¹⁰, R¹¹, and R¹² is hydrogen ora substituted hydrocarbon group.

In one more particular embodiment, Y is selected from a linear C₁-C₁₂ alkyl, and even more particularly, Y is C₁-C₁₂ alkyl. In one exemplary embodiment, Y is selected from CH₂, (CH₂)₂, (CH₂)₃, isopropyl. In an even more particular embodiment, Y is C₁ or C₂ alkyl, and in a still more particular embodiment C₂ alkyl.

Exemplary hydrolysable groups include C₁-C₁₂ alkoxy, C₁-C₁₂ alkylthio, C₁-C₁₂ haloalkoxy. Exemplary non-hydrolysable groups include C₁-C₁₂ alkyl, phenyl, aryl, vinyl, acrylate, epoxy, and acetyl. hi a more particular embodiment, each of R⁷, R⁸, and R⁹ is independently selected from a C₁-C₁₂ alkoxy. hi one exemplary embodiment, each of R⁷, R⁸, and R⁹is independently selected from methoxy and acetoxy. In one exemplary embodiment, each of R⁷, R⁸, and R⁹ is independently selected from methyoxy and ethoxy. In one exemplary embodiment, each of R⁷, R⁸, and R⁹ is ethoxy.

Exemplary substituted hydrocarbon groups include alkyl, aryl, epoxy, acetal, ether, and aryl groups. In one exemplary embodiment, each of R¹⁰, R¹¹, and R¹² is selected from hydrogen or C₁-C₁₂ alkyl, and even more particularly, each R¹⁰, R¹¹, and R¹²is independently selected from hydrogen or C₁-C₄ alkyl. In one exemplary embodiment, each R¹⁰, R¹¹, and R¹² is hydrogen.

In one embodiment, the carbonyl contributing monomer is methacryloxypropyltrimethoxysilane.Methacryloxypropyltrimethoxysilane is an acyclic monomer having the formula:

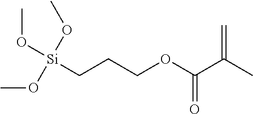 [SMILES: C=C(C)C(=O)OCCC[Si](OC)(OC)OC]

In one exemplary embodiment, the carbonyl contributing monomer is a carboxylic containing monomer of the formula:

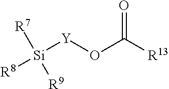

wherein: Y, R⁷, R⁸, and R⁹ are defined as above, and R¹³ is hydrogen or a substituted hydrocarbon group.

Exemplary substituted hydrocarbon groups include CH₃. In another exemplary embodiment, R¹³is selected from hydrogen or C₁-C₁₂ alkyl, ether, and epoxy, and even more particularly, R¹³ is selected from hydrogen or C₁-C₄ alkyl. In one exemplary embodiment, R¹³ is selected from methyl ethyl, propyl isopropyl, ether, and epoxy. In one exemplary embodiment, R¹³ is hydrogen.

In one exemplary embodiment, the carbonyl contributing monomer is an anhydride containing monomer of the formula:

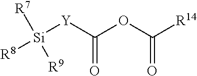

wherein: Y, R⁷, R⁸, and R⁹ are defined as above, and R¹⁴ is hydrogen or a substituted hydrocarbon group.

Exemplary substituted hydrocarbon groups include CH₃. In another exemplary embodiment, R¹⁴ is selected from hydrogen or C₁-C₁₂ alkyl, ether, and epoxy, and even more particularly, R¹⁴ is selected from hydrogen or C₁-C₄ alkyl. hi one exemplary embodiment, R¹⁴ is selected from methyl ethyl, propyl isopropyl, ether, and epoxy. In one exemplary embodiment, R¹⁴ is hydrogen.

### C. Additional Components

In addition to the carbosilane polymer, the composition from which the gap-filling or planarizing material is formed from may include one or more optional components, such as crosslink promoters, solvents, chromophores, catalysts, porogens, and surfactants. Additional organoalkoxysilane monomers may also be included.

### 1. Crosslink Promoters

In one embodiment, the composition includes at least one crosslink promoter.Exemplary crosslink promoters include aminosilane salts, such as APTEOS triflate, glycoluril, and similar crosslink promoters driven by an acid generating source such as thermal acid generators and photoacid generators.

In one embodiment, the crosslink promoter is an aminosilane salt of the formula:

Si(OR)₃(CH₂)ₙNH₃⁺(F₃CSO₃)⁻

wherein n is an integer from 1-10, each R is independently a C₁-C₂₀ alkyl. In a more particular embodiment, the crosslink promoter is an aminopropyltriethyl silane. An exemplary aminopropyl salt is APTEOS triflate, having the formula:

Si(OCH₂CH₃)₃(CH₂)₃NH₃⁺(F₃CSO₃)⁻

In one embodiment, the crosslink promoter comprises as little as about 0 wt. %, about 0.1wt. %, about 0.25 wt. %, about 0.5 wt. %, as great as about 1 wt. %, about2wt. %, about 5 wt. %, about 10 wt. %, of the total weight of the composition on a wet basis, or within any range defined by any two of the foregoing values, such as 0 wt. % to about 10 wt. %, about 0.1 wt. % to about 10 wt. %, or about 0.5 wt. % to about 1 wt. %.

### 2. Solvent

In one embodiment, the composition includes at least one solvent. Exemplary solvents include propylene glycol monomethyl ether acetate (PGMEA), alcohols such as ethanol and iso amyl alcohol, and water, as well as mixtures thereof.

In one embodiment, the solvent includes a planarizing enhancer. Exemplary planarizing enhancers include alkyl carbonates, such as propylene carbonate (PC). Without wishing to be bound by any theory, it is believed that the propylene carbonate acts as a surface tension modifier which aids in the planarizing effect of the solution when spin-applied applied to a substrate. Without wishing to be bound by any theory, it is believed that the effect of the planarizing enhancer in the solvent mixture is independent of the selection of monomers.

In one embodiment, the at least one solvent includes a first solvent and a second solvent. Exemplary first solvents include PGMEA and iso amyl alcohol. Exemplary second solvents include planaraizing enhancers, such as propylene carbonate. In one embodiment, the planarizing enhancer comprises as little as about 0 wt. %, about 2wt. %, about4wt. %, as great as about 5wt. %, about 7wt. %, about 7.1 wt. %, about 10 wt. %, of the total weight of the composition on a wet basis, or within any range defined by any two of the foregoing values.

In one embodiment, the total amount of solvent comprises as little as about 0 wt. %, about 20 wt. %, about40 wt. %, as great as about 50 wt. %, about 60 wt. %, about80 wt. %, of the total weight of the composition on a wet basis, or within any range defined by any two of the foregoing values.

### 3. Chromophore

In a more particular embodiment of any of the above embodiments, the composition further includes at least one chromophore. Exemplary chromophores include 9-anthracene carboxy-alkyl trialkoxysilanes, which absorb light at 248 nm, such as 9-anthracene carboxy-ethyl triethyoxysilane (TESAC), 9-anthracene carboxy-propyl trimethoxysilane, and 9-anthracene carboxy-propyl triethyoxysilane (ACTEP). Other exemplary chromophores include phenyl-containing silanes, such as phenyltriethoxy silane (PTEOS), which absorbs light at 193 nm. Other exemplary chromophores include vinyl TEOS and napthylene analogs of anthracene chromophores, such as found in U.S. Pat. No. 7,012,125, the disclosures of which are hereby incorporated by references. Exemplary chromophores include AH 2006, AH 2013, AH 2015, and AH 2016, the formulas for which are provided below.

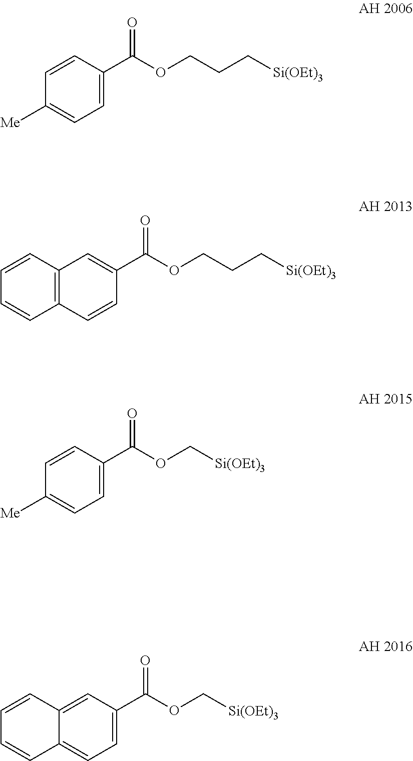

In one embodiment, the chromophore comprises as little as about 3 mol. %, about 5mol. %, about 10 mol. %, as great as about 20 mol. %, about 40 mol. %, about 60 mol.%, based on the total moles of monomer comprising the carbosilane polymer, or within any range defined by any two of the foregoing values, such as about 3 mol. % to about 60 mol. %, about 5 mol. % to about 40 mol. %, or about 10 mol. % to about 20 mol. %. In one embodiment, the chromophore comprises as little as about 3 wt. %, about 5wt. %, about 10 wt. %, about 20 wt. %, as great as about 25 wt. %, about 30 wt. %, about 35 wt. % about 40 wt%, about 60 wt. %, of the total weight of the composition on a dry film basis, or within any range defined by any two of the foregoing values, such as about 3 wt. % to about 60 wt. %, about 5 wt. % to about 40 wt. %, about 10 wt. % to about 35 wt. %, or about 20 wt. % to about 30 wt. %.

### 4. Catalyst

In a more particular embodiment of any of the above embodiments, the composition further includes at least one catalyst. Exernplary catalysts include tetramethyl ammonium nitrate (TMAN) and tetramethyl ammonium acetate (TMAA). Additional exemplary catalysts may be found in U.S. Pat. No. 8,053,159, the disclosures of which are hereby incorporated by reference in their entirety. In one embodiment, the catalyst comprises as little as about 0 wt. %, about 2 wt. %, about 4 wt. %, as great as about 5 wt. %, about 7 wt. %, about 10 wt. %, of the total weight of the composition on a wet basis, or within any range defined by any two of the foregoing values, such as about 2 wt. % to about 10 wt. %, about 2 wt. % to about 7 wt. %, about 4 wt. % to about 7 wt. %, or about 5 wt. % to about 7 wt. %.

### Organoalkoxysilane Monomers

In a more particular embodiment of any of the above embodiments, the carbosilane polymer is further formed from at leastone organoalkoxysilane monomer. In one even more particular embodiment, the at least oneorganoalkoxysilane monomer is selected from methyltrimethoxysilane (MTMOS), methyltriethoxysilane (MTEOS), dimethyldiethoxysilane (DMDEOS), phenyl triethoxysilane (PTEOS), dirnethyldimethoxysilane, phenyltrimethoxysilane, diphenyl diethoxysilane, diphenyl dimethoxysilane, and 9-anthracene carboxy-alkyl trialkoxysilanesand combinations of the foregoing.

In one exemplary embodiment, the organoalkoxysilane monomer is incorporated into the carbosilane polymer, and more particularly, into a backbone of the carbosilane polymer.

In one embodiment, the one or more organoalkoxysilane monomers comprise as little as about 0 wt. %, about 20 wt.%, about 40 wt. %, as great as about 50 wt. %, about 60 wt. %, about 80 wt. %, of the total weight of the composition on a wet basis, or within any range defined by any two of the foregoing values, such as 0 wt. % to about 80 wt. %, about 20 wt. % to about 60 wt. %, or about 40 wt. % to about 50 wt. %.

### D. Method of Forming Dried Film

### 1. Formation of the Carbosilane Polymer

In one embodiment, the carbosilane polymer is formed by reacting the carbosilane monomer and the carbonyl contributing monomer in a solvent solution to form the carbosilane polymer, Illustrative solvents include propylene glycol methyl ether acetate (PGMEA), ethanol, water, and mixtures thereof.

In one embodiment, the carbosilane polymer is formed by a catalyzed hydrolysis and condensation reaction. In a more particular embodiment, the hydrolysis and condensation reaction is an acid-catalyzed reaction. An acid, such as nitric acid, is added to the carbosilane monomer, carbonyl contributing monomer, and optionally, one or more additional components such as chromophores to form the reaction mixture.

In one embodiment, the reaction mixture is heated to initiate the polymerization reaction. In one embodiment, the reaction is heated to a temperature as little as 50° C., 55° C., 60° C., 65° C., as great as 70° C., 75° C., 80° C., 85° C., 90° C., for a time as little as 1 hour, 1.5 hours, 2 hours, as great as 2.5 hours, 3 hours, 3.5 hours, 4 hours, or longer.

In one embodiment, following the reaction the mixture may be cooled, and a suitable quenching agent, such as n-butanol, may be added to stop the reaction. Following cooling, the mixture may be diluted with an appropriate solvent, as such as PGMEA, and one or more optional components, such as a crosslink promoter, may be added.

In some embodiments, the mixture may be filtered through a fine pore filtration media to eliminate particles from the material.

### 2. Method of Forming Dried Film

In one embodiment, a film is formed from the composition including the carbosilane polymer. In one embodiment, the composition is applied to the substrate by spin-coating. The applied composition is then baked at a temperature as low as about ambient, about 50° C., about 100° C., about 120° C., as high as about 180° C., about 240° C., about 260° C., about 300° C., or within any range defined by any two of the foregoing values, such as about 50° C. to about 300° C., about 100° C. to about 260° C., about 120° C. to about 260° C., or about 180° C. to about 240° C. The applied composition is baked for as little as about 10 seconds, about 30 seconds, about 1 minute, as long as about 5 minutes, about 10 minutes, about 15 minutes, about60 minutes, or within any range defined by any two of the foregoing values, such as 10 seconds to 60 minutes, 1 minute to 15 minutes, or 5 minutes to 10 minutes.

In one exemplary embodiment, the applied composition is baked at 10° C. for 60 seconds, followed by 60 seconds at 240° C. in nitrogen atmosphere before being cooled to ambient.

### E. Compositions Comprising a Planarizing Enhancer

In one embodiment, a composition is provided including a silica source and at least one solvent, wherein the at least one solvent includes a planarizing enhancer. Exemplary silica sources include organoalkoxysilanes, carbosilane monomers, and carbonyl-contributing monomers.

In one exemplary embodiment, the silica source comprises one or more organoalkoxysilanes having the general formula:

R¹ₓSi(OR²)_{y}

where R1 is an alkyl, alkenyl, aryl, or aralkyl group, and x is an integer between 0 and 2, and where R2 is a alkyl group or acyl group and y is an integer between 1 and 4. In one embodiment, the silica source comprises an organoalkoxysilane selected from the group consisting of methyltrimethoxysilane (MTMOS), methyltriethoxysilane (MTEOS), dimethyldiethoxysilane (DMDEOS), phenyl triethoxysilane (PTEOS), dimethyldimethoxysilane, phenyltrimethoxysilane, and combinations of the foregoing.

In one exemplary embodiment, the silica source comprises one or more carbosilane monomers having the general formula:

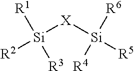

wherein: X is selected from linear or branched C₁-C₁₂ alkyl or C₆-C₁₄ aryl, and each R is a hydrolysable group or non-hydrolysable group. In one more particular embodiment, X is selected from a linear C₁-C₁₂ alkyl. In an even more particular embodiment, X is selected from methyl, ethyl, phenyl, diphenyl, ethylene, and naphyl. In a still more particular embodiment, X is ethyl. Exemplary hydrolysable groups include C₁-C₁₂ alkoxy, C₁-C₁₂ alkylthio, C₁-C₁₂ haloalkoxy. Exemplary non-hydrolysable groups include C₁-C₁₂ alkyl, phenyl, aryl, vinyl, acrylate, epoxy, and acetyl. In one exemplary embodiment, the silica source comprises one or more carbosilane monomers selected from the group consisting of 1,2-Bis(Triethoxysilyl)Ethane (BTSE), 1,2-Bis(Triethoxysilyl)Methane, 4,4-(Bis(triethyoxysilyl)-1,1 -biphenyl, and ,1,4-(Bis(triethoxysilyl)benzene.

In one exemplary embodiment, the silica source comprises one or more carbonyl contributing monomer. In one exemplary embodiment, the carbonyl contributing monomer is an acrylic monomer of the formula:

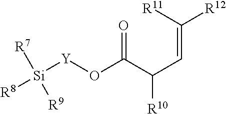

wherein: Y is selected from a linear or branched C₁-C₁₂ alkyl, each of R⁷, R⁸, and R⁹ is a hydrolysable group or non-hydrolysable group, and each of R¹⁰, R¹¹, and R¹² is hydrogen ora substituted hydrocarbon group. In one exemplary embodiment, the silica source comprises methacryloxypropyltrimethoxysilane.

In one exemplary embodiment, the carbonyl contributing monomer is a carboxylic containing monomer of the formula:

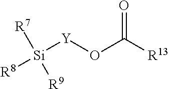

wherein: Y, R⁷, R⁸, and R⁹ are defined as above, and R¹³ is hydrogen or a substituted hydrocarbon group.

In one exemplary embodiment, the carbonyl contributing monomer s an anhydride containing monomer of the formula:

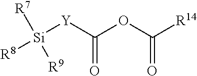

wherein: Y, R⁷, R⁸, and R⁹ are defined as above, and R¹⁴ is hydrogen or a substituted hydrocarbon group.

Exemplary solvents include propylene glycol monomethyl ether acetate (PGMEA), alcohols such as ethanol and iso amylalcohol, and water, as well as mixtures thereof.

In one embodiment, the solvent includes a planarizing enhancer. Exemplary planarizing enhancers include alkyl carbonates, such as propylene carbonate (PC). Without wishing to be bound by any theory, it is believed that the propylene carbonate acts as a surface tension modifier which aids in the planarizing effect of the solution when spin-applied applied to a substrate. Without wishing to be bound by any theory, it is believed that the effect of the planarizing enhancer in the solvent mixture is independent of the selection of monomers.

In one embodiment, the at least one solvent includes a first solvent and a planarizing enhancer. Exemplary first solvents include PGMEA and iso amyl alcohol. Exemplary planaraizing enhancers include propylene carbonate. In one embodiment, the planarizing enhancer comprises as little as about 0 wt. %, about 2 wt. %, about 4 wt. %, as great as about 5 wt. %, about 7 wt. %, about 7.1 wt. %, about 10 wt. %, of the total weight of the composition on a wet basis, or within any range defined by any two of the foregoing values.

In one embodiment, the total amount of solvent comprises as little as about 0 wt. %, about 20 wt. %, about 40 wt. %, as great as about 50 wt. %, about 60 wt. %, about 80 wt. %, of the total weight of the composition on a wet basis, or within any range defined by any two of the foregoing values.

### EXAMPLES

Exemplary polymers were prepared according to the Examples below.

### 1. Example#1:

To a 1 L flask set up on a mantle with condenser, thermocouple and stopper, 300.1 grams of propylene glycol monomethyl ether acetate, PGMEA (PPT grade) and 600 g of 3 A ethanol (toluene free) were added, and the resulting blend was stirred for 10 mins.

To this blend, 355 grams of monomer 1,2- (Bistriethoxysilyl)Ethane with molecular formula of C₁₄H₃₄O₆Si₂ was added, followed by 45 grams of 0.008N nitric acid. Cooling water to the condenser was turned on, and the mixture was reacted at 80° C. for 3 hours.

The reaction mixture was then avowed to cool down. At 67° C., the reaction was quenched by adding 44.2 grams of n-butanol. The reaction mixture was allowed to cool down to room temperature and remain at this temperature overnight.

The reaction mixture was then diluted with about 30 wt. % to about 80 wt. % PGMEA (PPT grade) to the target film thickness, After dilution, 8500 ppm of APTEOS-tirflate was added to the final formulation. This solution was mixed for an hour to ensure homogeneity, followed by filtering the solution through a fine pore filtration media to eliminate particles from the material.

### 2. Example#2:

To a 1L flask set up on a mantle with condenser, thermocouple, and stopper, 39.7 grams of 9-anthracene carboxy-methyl triethoxysilane (TESAC) was added followed by the addition of 300.1 grams of PGMEA (PPT grade), and 600g of 3A ethanol (toluene free) with continuous stirring until the TESAC dissolved completely.

To this blend, 141.84 grams of monomer 1,2- (Bistriethoxysilyl)Ethane with molecular formula of C₁₄H₃₄O₆Si₂ was added, along with 36 grams of 0.008N Nitric acid solution. Cooling water to the condenser was turned on, and the mixture was reacted at 60° C. for 2 hours.

The reaction mixture was then allowed to cod down. At 57° C., the reaction was quenched by adding 44.2 grams of n-butanol. The reaction mixture was allowed to cod down to room temperature and remain at this temperature overnight.

The reaction mixture was then diluted with PGMEA (PPT grade) to the target film thickness.After dilution, 3400 ppm of APTEOS triflatewas added to the final formulation. This solution was mixed for an hour to ensure homogeneity, followed by filtering the solution through a fine pore filtration media to eliminate particles from the material.

### 3. Example#3:

To a 1L flask set up on a mantel with a condenser, thermocouple and stopper, 300.1 grams of PGMEA (PPT grade) and 600g of 3A ethanol (toluene free) were added, and the resulting blend was stirred for 10 mins.

To this blend, 141.84 grams of monomer 1,2- (Bistriethoxysilyl)Ethane with molecular formula of C₁₄H₃₄O₆Si₂ and 43 grams of Phenyltriethoxysilane (PTEOS) were added with continuous stirring, followed by 36 grams of 0.008N Nitric acid. Cooling water to the condenser was turned on, and the mixture was reacted at 70° C. for 3 hours.

The reaction mixture was then avowed to cool down. At 57° C., the reaction was quenched by adding 44.2 grams of n-butanol. The reaction mixture was allowed to cool down to room temperature and remain at this temperature overnight.

The reaction mixture was then diluted with PGMEA (PPT grade) to the target film thickness. After dilution, 8500 ppm of APTEOS triflate was added to the final formulation. This solution was mixed for an hour to ensure homogeneity, followed by filtering the solution through a fine pore filtration media to eliminate particles from the material.

### 4. Example#4:

To a 1L flask set up on a mantle with a condenser, thermocouple, and a stopper, 300,1 grams ofPGMEA (PPT grade) and 600g of 3A ethanol (toluene free) were added, and the resulting blend was stirred for 10 mins.

To this blend, 340.56grams of monomer (Bistriethoxysilyl)Methane with molecular formula of C₁₃H₃₂O₆Si₂ was added, followed by 0.008N nitric acid. The amount of acid solution amount was varied from 45 grams-81 grams, resulting in homopolymer with a MW range of 720 amu-1750 amu. Cooling water to the condenser was turned on, and the mixture was reacted at 80° C. for 3 hours.

The reaction mixture was then allowed to cool down. At 67° C., the reaction was quenched by adding 44.2 grams of n-butanol. The reaction mixture was allowed to cool down to room temperature and remain at this temperature overnight.

The reaction mixture was then diluted with PGMEA (PPT grade) to the target film thickness. After dilution, 3600 ppm of APTEOS-triflate was added to the final formulation. This solution was mixed for an hour to ensure homogeneity, followed by filtering the solution through a fine pore filtration media to eliminate particles from the material.

### 5. Example#5:

To a 1L flask set up on a mantle with a condenser, a thermocouple, and a stopper, 300.1 grams of PGMEA (PPT grade) and 600g of 3A ethanol (toluene free) were added, and the resulting blend was stirred for 10 mins.

To this blend, 306.5 grams of monomer (Bistriethoxysilyl)Methane with molecular formula of C₁₃H₃₂O₆Si₂ and 47.8 grams of 4,4-(Bis(Triethoxysilyl)-1,1-Biphenyl with a molecular formula of C₂₄H₃₈O₆Si₂ were added, followed by 0.008N nitric acid, The amount of acid solution amount was varied from 45 grams-81 grams, resulting in homopolymer with a MW range of 720 amu-1750 amu. Cooling water to the condenser was turned on, and the mixture was reacted at 60° C. for 3 hours.

The reaction mixture was then allowed to cool down. At 57° C., the reaction was quenched by adding 44.2 grams of n-butanol. The reaction mixture was allowed to cool down to room temperature and remain at this temperature overnight.

The reaction mixture was then diluted with PGMEA (PPT grade) to the target film thickness. After dilution, 3600 ppm of APTEOS triflate was added to the final formulation. This solution was mixed for an hour to ensure homogeneity, followed by filtering the solution through a fine pore filtration media to eliminate particles from the material.

### 6. Example#6:

To a 1L flask set up on a mantle with a condenser, a thermocouple, and a stopper, 300.1 grams of PGMEA (PPT grade) and 600g of 3A ethanol (toluene free) are added, and the resulting blend was stirred for 10 mins.

To this blend, 248.35 grams of 3-methacryloxypropyltrimethoxysilane was added, followed with the addition of 36 grams of 0,008N Nitric Acid. Cooling water to the condenser was turned on, and the mixture was reacted at 80° C. for 3 hours.

The reaction mixture was then allowed to cool down, At 57° C., the reaction was quenched by adding 44.2 grams of n-butanol. The reaction mixture was allowed to cool down to room temperature and remain at this temperature overnight.

The reaction mixture was then diluted with PGMEA (PPT grade) to the target film thickness. After dilution, 8500 ppm of APTEOS triflate was added to the final formulation. This solution was mixed for an hour to ensure homogeneity.

### 7. Example#7

To a 1L flask set up on a mantle with a condenser, thermocouple, and stopper, 300.1 grams of PGMEA (PPT grade) and 600g of 3A ethanol (toluene free) were added, and the resulting blend was stirred for 10 mins.

To this blend, the monomers 1,2- (Bistriethoxysilyl)Ethane and 3-methacryloxypropyltrimethoxysilane with a molecular formula C₁₀H₂₂O₄Si were added. The amounts of the siloxane monomers were varied from 283.67grams of (Bistriethoxysilyl)Ethane and 49.67 grams of 3-methacryloxypropyltrimethoxysilane to 0 grams of 3-methacryloxypropyltrimethoxysilane and 248.35 grams 3-methacryloxypropyltrimethoxysilane. The weight percentage of silicon was changed from 19.9 wt. % to 35.7 wt. % by varying the amounts of the siloxane monomers. To this mixture, 36 grams of 0.008N Nitric Acid was added. Cooling water to the condenser was turned on, and the mixture was reacted at 60° C. for 2 hours.

The reaction mixture was then allowed to cool down. At 57° C., the reaction was quenched by adding 44.2 grams of n-butanol. The reaction mixture was allowed to cool down to room temperature and remain at this temperature overnight.

The reaction mixture was then diluted with PGMEA (PPT grade) to the target film thickness. After dilution, 8500 ppm of APTEOS triflate was added to the final formulation. This solution was mixed for an hour to ensure homogeneity, followed by filtering the solution through a fine pore filtration media to eliminate particles from the material.

Referring next to Table 1, materials with varying silicon content were made using the method of Example 7 by varying the amount of the carbosilane monomer (BTSE) and carbonyl-containing monomer (3-methacryloxypropyltri-methoxysilane. The control material contained no carbonyl-containing monomer. Each material was cast at 1500 rpm on to 300 mm wafers and baked at 130° C. for 60 seconds, followed by 220° C. for 60 seconds.

The etching properties of each film were determined in the ^{.}following solvents: PGMEA at room temperature for 1 minute, 2.38% TMAH at room temperature for 1 minute, aqueous base stripper CLk-888 at room temperature for 1 minute, CLk-888 at 30° C. for 1 minute, CLk-888 at 50° C. for 1 minute, and ammonium hydroxide at 40° C. for 1 minute. The percentage change in film thickness for each material following exposure is presented in Table 1. Negative values are due to film swelling.

TABLE 1
Wet etch data for Example 7

| | PGMEA | TMAH | CLk-888 | CLk-888 | CLk-888 | NH₄OH at |
|---|---|---|---|---|---|---|
| Material | at RT | at RT | at RT | at 30° C. | at 50° C. | 40° C. |
| Control | −3% | −1% | −3% | −2% | 100% | 0% |
| (42.5 wt. % Si) | | | | | | |
| 35.7 wt. % Si | −5% | 0% | 1% | 1% | 100% | 0% |
| 29.8 wt. % Si | 0% | 0% | 1% | 4% | 100% | 1% |
| 24.5 wt. % Si | 3% | 4% | 5% | 8% | 100% | 4% |
| 19.9 wt. % Si | −2% | −2% | 5% | 9% | 100% | 5% |

As shown in Table 1, each film was completely removed in CLk-888 at 50° in 1 minute, and all films were resistant to PGMEA at room temperature for 1 minute. Decreasing the silicon content in the material led to an improvement in the stripping rate of CLk-888 at room temperature and at 30° C.

### 8. Exampie#8:

To a 1L flask set up on a mantle with a condenser, a thermocouple and a stopper, 39.7 grams of 9-anthracene carboxy-methyl triethoxysilane (TESAC) was added followed by the addition of 300.1 grams of PGMEA (PPT grade) and 600 g of 3 A ethanol (toluene free) with continuous stirring until the TESAC dissolved completely.

To this blend, the monomers 1,2- (Bistriethoxysilyl)Ethane and 3-methacryloxypropyltrimethoxysilane with a molecular formula C₁₀H₂₂O₄Si are added to the solvent blend. The amounts of the monomers were varied from 88.65 grams of (Bistriethoxysilyl)Ethane and 37.25 grams of 3-methacryloxypropyltrimethoxysilane to 0 grams of 1,2- (Bistriethoxysilyl)Ethane and 198.68 grams 3-methacryloxypropyltrimethoxysilane. The weight percentage of silicon was changed by varying the amounts of the siloxane monomers. To this mixture, 36 grams of 0.008N nitric acid was added. Cooling water to the condenser was turned on, and the mixture was reacted at 60° C. for 2 hours.

The reaction mixture was then allowed to cool down. At 57° C., the reaction was quenched by adding 44.2 grams of n-butanol. The reaction mixture was allowed to cool down to room temperature and remain at this temperature overnight.

The reaction mixture was then diluted with PGMEA (PPT grade) to the target film thickness. After dilution, 3400 ppm of Aminipropyltriethoxysilane was added to the final formulation. This solution was mixed for an hour to ensure homogeneity, followed by filtering the solution through a fine pore filtration media to eliminate particles from the material.

Referring next to Table 2, materials with varying silicon content were made using the method of Example 8 by varying the amount of the carbosilane monomer (BTSE) and carbonyl-containing monomer (3-methacryloxypropyltri-methoxysilane. The control material contained no carbonyl-containing monomer. Each material was cast at 1500 rpm on to 300 mm wafers and baked at 130° C. for 60 seconds, followed by 240° C. for 60 seconds.

The etching properties of each film were determined in the following solvents: an SC-1 solution (Standard Clean-1, comprising 1 part of 29% aqueous NH₄OH, 18 parts 30% aq. H₂O₂, and 60 parts DI water by volume) at 70° C. for 1 minute, 2.38% TMAH at room temperature for 1 minute, aqueous base stripper CLk-888 at room temperature for 1 minute, CLk-888 at 30° C. for 1 minute, and 29% ammonium hydroxideat 40° C. for 1 minute. The percentage change in film thickness for each material following exposure is presented in Table 2. Negative values are due to film swelling.

TABLE 2
Wet etch data for Example 8

| | SC-1 at | TMAH | CLk-888 | CLk-888 | NH₄OH |
|---|---|---|---|---|---|
| Material | 60° C. | a tRT | at RT | at 30° C. | a t40° C. |
| Control | −2% | 0% | −1% | 100% | 0% |
| (31 wt. % Si) | | | | | |
| 28.4 wt. % Si | 1% | 1% | 1% | 100% | −3% |
| 23.8 wt. % Si | 1% | 1% | 1% | 100% | 7% |
| 19.6 wt. % Si | 4% | 4% | 100% | 100% | 5% |
| 15.8 wt. % Si | 6% | 11% | 100% | 100% | 7% |

As shown in Table 2, each film was completely removed in CLk-888 at 30° in 1 minute, The strip rate under mild room temperature CLk-888 increased as the silicon weight percentage decreased. An increase from 0% to 60% removal was obtained by decreasing the silicon content from 31 wt. % to 23.8 wt. %, and an increase to 100% removal was obtained by further decreasing the silicon content to 19.6 wt. % or lower. Decreasing the silicon content in the material led to an improvement in the stripping rate of CLk-888 at room temperature and at 30° C.

The average etch rate in SC-1 at 70° C. is provided in Table 3 below.

TABLE 3
Wet etch rate for Example 8

| | | Average |
|---|---|---|
| Material | Bake conditions | Etch Rate |
| Control | 140° C./220° C., 60 sec each | −1 |
| (31 wt. % Si) | | |
| 23.8 wt. % Si | 140° C./220° C., 60 sec each | 2 |
| 19.6 wt. % Si | 140° C./220° C., 60 sec each | 31 |

As shown in Table 3, the average wet etch rate increased as the silicon content decreased.

Referring next to Table 4 and FIGS. 3 and 4, plasma etch data for the control and 20 wt. % and 24 wt. % silicon materials are illustrated, along with plasma etch data for silane oxide. FIG. 3 illustrates the etch rate in A/min in an Applied Materials (MxP) plasma etch tool at 100 mT, 250W using a 45/30/22 composition of CF₄/Ar/O₂. FIG. 4 illustrates the etch rate in A/min at 300 mT, 800W using a 30/500/30 composition of CF₄/Ar/CHF₃.

TABLE 4
Plasma etch rate for Example 8

| | Etch rate | Etch rate |
|---|---|---|
| Material | (CF₄/Ar/O₂) | (CF₄/Ar/CHF₃) |
| Control | 1262 | 2799 |
| (31 wt. % Si) | | |
| 23.8 wt. % Si | 4031 | 1333 |
| 19.6 wt. % Si | 3833 | 1105 |

As illustrated in FIG. 3, the plasma etch rate for CF₄/Ar/O₂ increases as the silicon weight percentage decreases. The 20 wt. % silicon material had a 5 time faster etch rate compared to silane oxide. However, as illustrated in FIG. 4, the plasma etch rate for CF4/Ar/CHF₃ decreases as the silicon weight percentage decreases. In FIG. 4, a lower silicon content resulted in a reduction in plasma etch rate.

Referring next to Table 5, additional samples of the 15.8 wt. % Si samples from Table 2 above, except that one set of samples was diluted with PGMEA only, while a second set of samples was diluted with a blend of PGMEA and propylene carbonate. Gel permeation chromatography was performed on both sets of samples. The number average molecular weight (Mₙ), the weight average molecular weight (M_{w}), and the polydispersity (PD=M_{w}/Mₙ) of each sample are provided in Table 5.

TABLE 5
GPC results for Examble 8

| Material | Mₙ | M_{w} | PD |
|---|---|---|---|
| 15.8 wt. % Si, PGMEA only | 645 | 723 | 1.1205 |
| 15.8 wt. % Si, PGMEA/PC blend | 655 | 732 | 1.1165 |

Referring next to Tables 6 and 7, the etch properties of the 23.8 wt. % silicon material and the 19.6 wt. % silicon material of Table 2 were sought to be optimized by varying the baking conditions. Additional films were prepared as above, but each material was baked according to the conditions given in Table 6 or Table 7.

The etching properties of each film were determined in the following solvents: PGMEA at room temperature for 1 minute, 2.38% TMAH at room temperature for 1 minute, CLk-888 at room temperature for 1 minute,SC-1 solution (Standard Clean-1, comprising 1 part of 29% aqueous NH₄OH, 18 parts 30% aq. H₂O₂, and 60 parts DI water by volume) at 40° C. for 3 minutes, and 98% n-butyl acetate at room temperature for 1 minute. The percentage change in film thickness for each material following exposure is presented in Tables 6 and 7. Negative values are due to film swelling.

TABLE 6
Additional wet etch data for 15.8 wt. % Si
silicon material diluted with PGMEA only

| | | PGMEA | TMAH | CLk-888 | SC1 at | |
|---|---|---|---|---|---|---|
| Material | Bake conditions | at RT | at RT | at RT | 40° C. | nBA |
| 15.8 wt. % Si, | 140° C./200° C., | 23% | 1% | 100% | 21% | 3% |
| PGMEA | 60 sec each | | | | | |
| 15.8 wt. % Si, | 140° C./210° C., | 15% | 8% | 100% | 11% | 1% |
| PGMEA | 60 sec each | | | | | |
| 15.8 wt. % Si, | 140° C./220° C., | 12% | 0% | 100% | 11% | 0% |
| PGMEA | 60 sec each | | | | | |
| 15.8 wt. % Si, | 140° C./230° C., | 8% | 1% | 100% | 6% | 0% |
| PGMEA | 60 sec each | | | | | |
| 15.8 wt. % Si, | 140° C./240° C., | 6% | 2% | 100% | 4% | −2% |
| PGMEA | 60 sec each | | | | | |
| 15.8 wt. % Si, | 140° C./250° C., | 9% | −2% | 100% | 2% | 0% |
| PGMEA | 60 sec each | | | | | |

As shown in Table 6, each film was completely removed in CLk-888. A reduction in film thickness in PGMEA was observed, particularly for baking conditions less than 230° C. in the second step.

TABLE 7
Additional wet etch data for 15.8 wt. % Si silicon
material diluted with PGMEA/PC blend

| | | PGMEA | TMAH | CLk-888 | SC1 at | |
|---|---|---|---|---|---|---|
| Material | Bake conditions | at RT | at RT | at RT | 40° C. | nBA |
| 15.8 wt. % Si, | 140° C./200° C., | 23% | 1% | 100% | 3% | 20% |
| PGMEA/PC | 60 sec each | | | | | |
| 15.8 wt. % Si, | 140° C./210° C., | 19% | 5% | 100% | 3% | 16% |
| PGMEA/PC | 60 sec each | | | | | |
| 15.8 wt. % Si, | 140° C./220° C., | 13% | 4% | 100% | 1% | 10% |
| PGMEA/PC | 60 sec each | | | | | |
| 15.8 wt. % Si, | 140° C./230° C., | 8% | 4% | 100% | 5% | 7% |
| PGMEA/PC | 60 sec each | | | | | |
| 15.8 wt. % Si, | 140° C./240° C., | 3% | 5% | 100% | 1% | 6% |
| PGMEA/PC | 60 sec each | | | | | |
| 15.8 wt. % Si, | 140° C./250° C., | 3% | 0% | 100% | 0% | 6% |
| PGMEA/PC | 60 sec each | | | | | |

As shown in Table 7, each film was completely removed in CLk-888. A reduction in film thickness in PGMEA was observed, particularly for baking conditions less than about 230° C. or 240° C. in the second step,

Referring next to Table 8,the etch properties of the 15.8 wt. % silicon material of Table 2 was investigated. Additional films were prepared as above, but each material was baked for 60 seconds at 140° C., followed by 60 seconds at 240° C.

The etching properties of each film were determined in the following solvents: SC-1 solution (Standard Clean-1, comprising 1 part of 29% aqueous NH₄OH, 18 parts 30% aq. H₂O2, and 60 parts DI water by volume) at 70° C. for 3 minutes PGMEA at room temperature for 1 minute, 2.38% TITIAN at room temperature for 1 minute, CLk-888 at room temperature for 1 minute,98% n-butyl acetate at room temperature for 1 minute, and 29% ammonium hydroxide at 40° C. for 1 minute. The percentage change in film thickness for each material following exposure is presented in Table 8.

TABLE 8
Additional wet etch data for 15.8 wt. % silicon material

| | SC1 at | PGMEA | TMAH | CLk-888 | | |
|---|---|---|---|---|---|---|
| Material | 40° C. | at RT | at RT | at RT | nBA | NH₄OH |
| 15.8 wt. % Si | 4% | 4% | 1% | 100% | 1% | 1% |

As shown in Table 8, each film was completely removed in CIA-888. The baked film was resistant to PGMEA, 2.38% TMAH, and n-butyl acetate.

### 9. Example#9

To a 1L flask set up on a mantle with a condenser, a thermocouple, and a stopper, 300.1 grams of Propylene Glycol Monomethyl Ether Acetate, PGMEA (PPT grade) and 600 g of 3 A Ethanol (toluene free) were added with continuous stirring.

To this blend varying amounts of 1,2- (Bistriethoxysilyl)Ethane, Phenyltriethoxysilane and 3-methacryloxypropyltrimethoxysilane were added followed with the addition of 36 grams of 0.008N Nitric Add. The reaction mixture was reacted at 70 C. for 3 hrs.

The reaction mixture was then allowed to cool down. At 57° C., the reaction was quenched by adding 44.2 grams of n-butanol. The reaction mixture was allowed to cool down to room temperature and remain at this temperature overnight.

The reaction mixture was then diluted with PGMEA (PPT grade) to the target film thickness. After dilution, 8500 ppm of Aminipropyltriethoxysilane was added to the final formulation. This solution was mixed for an hour to ensure homogeneity.

Referring next to Table 9, materials with varying silicon content were made using the method of Example 9 by varying the amount of the carbosilane monomer (BTSE) and the monomer (TESAC). The control material contained no TESAC. Each material was cast at 1500 prm on to 300 mm wafers and baked at 130° C. for 60 seconds, followed by 220° C. for 60 seconds.

The etching properties of each film were determined in the following solvents: PGMEA at room temperature for 1 minute, 2.38% TMAH at room temperature for 1 minute, CLk-888 at room temperature for 1 minute, and CLk-888 at 30° C. for 1 minute. The percentage change in film thickness for each material following exposure is presented in Table 9. Negative values are due to film swelling,

TABLE 9
Wet etch data for Example 9

| | PGMEA | TMAH | CLk-888 | CLk-888 |
|---|---|---|---|---|
| Material | at RT | at RT | at RT | at 30° C. |
| Control | −1% | −1% | 0% | 100% |
| (36.2 wt. % Si) | | | | |
| 26.97 wt. % Si | 1% | −4% | 37% | 100% |
| 20.4 wt. % Si | −1% | 1% | 83% | 100% |
| 15.6 wt. % Si | −2% | 4% | 100% | 100% |

As shown in Table 9, each film was completely removed in CLk-888 at 30° in 1 minute, and all films were resistant to PGMEA at room temperature for 1 minute. All films were resistant to 2.3% TMAH at room temperature except the 15.6 wt. % Si sample, which had 4% film thickness removed. However, the strip rate under mold room temperature with CLk-888 was increased from 0% to full removal (100%) by decreasing the weight percentage of silicon from 36.2 wt. % to 15.6 wt. %.

Referring next to Table 10, the etch properties of the 15.6 wt. % silicon material were sought to be optimized by varying the baking conditions. Additional films were prepared as above, but each material was baked according to the conditions given in Table 10.

The etching properties of each film were determined in the following solvents: PGMEA at room temperature for 1 minute, 2.38% TMAH at room temperature for 1 minute, and CLk-888 at room temperature for 1 minute. The percentage change in film thickness for each material following exposure is presented in Table 10. Negative values are due to film swelling.

TABLE 10
Additional wet etch data for Example 9

| | | | | CLk- |
|---|---|---|---|---|
| | | PGMEA | TMAH | 888 |
| Material | Bake conditions | at RT | at RT | at RT |
| 15.6 wt. % Si | 130° C./200° C., | −2% | 4% | 100% |
| | 60 sec each | | | |
| 15.6 wt. % Si | 130° C./220° C., | 2% | 3% | 100% |
| | 90 sec each | | | |
| 15.6 wt. % Si | 130° C./230° C., | 0% | 1% | 100% |
| | 60 sec each | | | |
| 15.6 wt. % Si | 130° C./230° C., | −2% | 1% | 100% |
| | 90 sec each | | | |
| 15.6 wt. % Si | 130° C./240° C., | −8% | 1% | 86% |
| | 60 sec each | | | |
| 15.6 wt. % Si | 130° C./240° C., | 1% | 1% | 50% |
| | 90 sec each | | | |

As shown in Table 10, each film was completely removed in CLk-888 at 30° in 1 minute. Additionally, the resistance to 2% TMAH at room temperature was improved by increasing the baking temperature. Additionally, 100% removal was achieved at 15.5 wt. % for samples baked at 130° C./220° C. or 130° C/230° C.

### 10. Example#10

To a 1 L flask set up on a mantle with condenser, thermocouple, and stopper, 45.44 grams of 9-anthracene carboxy-methyl triethoxysilane (TESAC) was added followed by the addition of 150.05 grams of Iso Amyl Alcohol, IAA, and 300 g of 2 B ethanol with continuous stirring until the TESAC dissolved completely.

To this blend, 124.8 grams of monomer Tetraethoxysilane with molecular formula of (C₂H₅O)₄Si and 77.7 grams of Methyl triethoxysilane with molecular formula CH₃Si(OC₂H₅)₃ was added, along with 73.2 grams of 0.008N nitric acid solution. Cooling water to the condenser was turned on, and the mixture was reacted at 60° C. for 3 hours.

The reaction mixture was then allowed to cool down. At 57° C., the reaction was quenched by adding 44.2 grams of n-butanol. The reaction mixture was allowed to cool down to room temperature and remain at this temperature overnight.

The reaction mixture was then diluted withiso amyl alcohol (IAA).

A similar example was prepared according to the above method, except that the reaction mixture was diluted with a solvent blend of iso amyl alcohol (IAA) and propylene carbonate (PC) to the target film thickness. The dilution solvent blend was prepared by adding 100 grams of propylene carbonate to 900 g grams of Iso Amyl Alcohol. This solution was mixed for an hour to ensure homogeneity, followed by filtering the solution through a fine pore filtration media to eliminate particles from the material.

Both formulations were coated on patterned wafers with large pad like featuers (14 μm×45 μm×60 μm), global planarity was determined by scanning electron microscope (SEM) analysis. The results are provided in Table 11

TABLE 11
Comparison of global planarity

| | Global |
|---|---|
| Material | planarity |
| IAA solvent | 78.0 |
| IAA solvent + PC planarizing enhancer | 47.6 |

As shown in Table 11, the material diluted with the solvent including the planarizing enhancer resulted in a 39% improvement in planarity compared to the material diluted with the solvent lacking the planarizing enhancer.

### 11. Example#11

To a 1 L flask set up on a mantle with condenser, thermocouple, and stopper, 39.7 grams of 9-anthracene carboxy-methyl triethoxysilane (TESAC) was added followed by the addition of 150.05 grams of propylene glycol monomethyl ether acetate, PGMEA (PPT grade) and 300 g of 3 A ethanol (toluene free) are added with continuous stirring until the TESAC dissolved completely.

To this blend, 17.7 grams of 1,2- (Bistriethoxysilyl)Ethane and 86.9 grams of 3-methacryloxypropyltrimethoxysilane with a molecular formula C₁₀H₂₂O₄Si were added., along with 36 grams of 0.008N nitric acid solution. Cooling water to the condenser was turned on, and the mixture was reacted at 60° C. for 3 hours.

The reaction mixture was then allowed to cool down. At 57° C., the reaction was quenched by adding 44.2 grams of n-butanol. The reaction mixture was allowed to cool down to room temperature and remain at this temperature overnight.

The reaction mixture was then diluted withpropylene glycol monomethyl ether acetate, PGMEA (PPT grade).

A similar example was prepared according to the above method, except that the reaction mixture was diluted with a solvent blend of propylene glycol monomethyl ether acetate, PGMEA (PPT grade) and propylene carbonate (PC) to the target film thickness. The dilution solvent blend was prepared by adding 100 grams of propylene carbonate to 900 g grams of PGMEA (PPT grade). This solution was mixed for an hour to ensure homogeneity, followed by filtering the solution through a fine pore filtration media to eliminate particles from the material.

Both formulations were coated on patterned wafers with large pad like featuers (14 μm×45 μm×60 μm), global planarity was determined by scanning electron microscope (SEM) analysis. The results are provided in Table 11

TABLE 12
Comparison of global planarity

| | Global |
|---|---|
| Material | planarity |
| PGMEA solvent | 14.5 |
| PGEMA solvent + PC planarizing enhancer | 7.5 |

As shown in Table 11, the material diluted with the solvent including the planarizing enhancer resulted in a 50% improvement in planarity compared to the material diluted with the solvent lacking the planarizing enhancer.

While this invention has been described as having exemplary designs, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

1-10. (canceled)

11. A composition comprising:
a carbosilane polymer formed from at least one carbosilane monomer and at least one carbonyl contributing monomer, the carbosilane polymer having a silica content of 10 wt. % to 45 wt. % or a carbonyl content of 3 wt. % or greater.

12. The composition of claim 11, wherein the carbosilane polymer has a silica content of 10 wt. % to 45 wt. %.

13. The composition of claim 11, wherein the carbosilane polymer has a carbonyl content of 3 wt. % or greater.

14. The composition of claim 11, wherein the carbosilane monomer is of the formula: 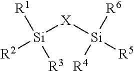
wherein: X is selected from linear or branched C₁-C₁₂ alkyl or C₆-C₁₄ aryl, and
each R is a hydrolysable or non-hydrolysable group.

15. The composition of claim 11, wherein the carbosilane monomer is Bis(Triethoxysilyl)Ethane.

16. The composition of claim 11, wherein the carbonyl contributing monomer includes a moiety selected from an acrylic moiety, a carboxylic moiety, and an anhydride moiety.

17. The composition of claim 11, wherein the carbonyl contributing monomer is of the formula: 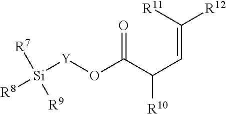
wherein: Y is selected from a linear or branched C₁-C₁₂ alkyl,
each of R⁷, R⁸, and R⁹ is a hydrolysable group or non-hydrolysable, and
each of R¹⁰, R¹¹, R¹² is hydrogen or a substituted hydrocarbon group.

18. The composition of claim 11, wherein the carbonyl contributing monomer is methacryloxypropyltrimethoxysilane.

19. The composition of claim 11, further comprising at least one crosslink promoter.

20. The composition of claim 11, further comprising at least one solvent.

21. The composition of claim 19, wherein the solvent comprises propylene carbonate.

22. The composition of claim 11, wherein the carbosilane polymer has a molecular weight of 5,000 or less.

23. The composition of claim 11, further comprising at least one chromophore.

24. The composition of claim 11, further comprising at least one organoalkoxysilane monomer.

25. A composition comprising:
at least one monomer selected from a carbosilane monomer, a carbonyl contributing monomer, and an organoalkoxysilane monomer; and
at least one solvent, wherein the solvent comprises a planarizing enhancer.

26. The composition of claim 24, wherein the at least one monomer includes at least one organoalkoxysilane monomer selected form the group consisting of methyltrimethoxysilane (MTMOS), methyltriethoxysilane (MTEOS), dimethyldiethoxysilane (DMDEOS), phenyl triethoxysilane (PTEOS), dimethyldimethoxysilane, and phenyltrimethoxysilane.

27. A method of forming a carbosilane polymer comprising:
reacting at least one carbosilane monomer and at least one carbonyl contributing monomer to form the carbosilane polymer, wherein the carbosilane polymer has a silica content of 13 wt. % to 30 wt. %.

28. The method of claim 27, wherein the carbosilane polymer has a carbonyl content of 3 wt. % or greater.

29. The method of claim 27, wherein the carbosilane monomer component is Bis(Triethoxysilyl)Ethane.

30. The method of claim 27, further comprising polymerizing the carbosilane polymer with a crosslink promoter to form a film.
